(19) United States
(12) Patent Application Publication
(10) Pub. No.: US 2025/0132188 A1
(43) Pub. Date: Apr. 24, 2025

(54) PLASMA PROCESSING APPARATUS

(71) Applicant: Hitachi High-Tech Corporation, Minato-ku, Tokyo (JP)

(72) Inventors: Ryota ISHIBASHI, Tokyo (JP); Shengnan YU, Tokyo (JP); Kohei SATO, Tokyo (JP)

(21) Appl. No.: 18/692,561

(22) PCT Filed: Dec. 26, 2022
(86) PCT No.: PCT/JP2022/048060

§ 371 Date: Mar. 15, 2024

(51) Int. Cl. H01L 21/687; H01J 37/32

(52) U.S. Cl. CPC H01L 21/68735; H01J 37/32458; H01J 37/32715; H01L 21/68785; H01J 2237/334

(57) ABSTRACT

Provided is a plasma processing apparatus that improves exhaust conductance in a vacuum vessel and generates stable plasma. The plasma processing apparatus has a plurality of drive actuators disposed outside the vacuum vessel, and the drive actuators and an outer peripheral portion of the bottom surface of a sample stage are connected to each other by a plurality of arms. The sample stage is driven upwards and downwards by driving the arms upwards and downwards using the drive actuators. Cables and the arms connected to the sample stage for power supply are vertically arranged in parallel, sliding of the cables is suppressed by performing a wiring route of the cables along the arms, and the volume of the vacuum vessel occupied by a sample stage unit is reduced.

### TECHNICAL FIELD

The present disclosure relates to a plasma processing apparatus.

### BACKGROUND ART

In order to improve uniformity of plasma processing on a wafer to be processed, a plasma processing apparatus is required to discharge a reaction product generated during the plasma processing using a vacuum pump installed below a sample stage. Meanwhile, as one of the plasma processing parameters for the wafer to be processed, the plasma processing apparatus drives a height of the sample stage under processing upwards and downwards using a drive actuator or the like in order to adjust the volume of a discharge area having plasma generated therein, in which the discharge area is a space formed above the upper surface of the sample stage.

In order to improve accuracy of wafer processing, recently, a plasma processing apparatus has been developed so as to have a configuration including a discharge area in which a sample stage supporting a wafer is disposed at a central portion of a processing chamber in the vertical direction, the processing chamber is a space above an upper surface of the sample stage, and plasma is generated therein; an exhaust area facing an exhaust port which is a space below a bottom surface of the sample stage and is located directly below the bottom surface; and a space on the outer peripheral side of an outer wall of the sample stage, in which the space connects the discharge area to the exhaust area so as to perform communication therebetween. Such technology reduces circumferential variations in a flow of gas and particles in the processing chamber from the space above the upper surface of the sample stage where plasma is generated to the exhaust area, thereby improving processing accuracy.

An example of a proposal for the above-described plasma processing apparatus including a vacuum vessel structure and a vertical drive mechanism is disclosed in JP2020-109847A (PTL 1). PTL 1 discloses that an actuator assembly 192 can be coupled to a hollow shaft 178 so as to move a substrate support assembly 118 in the vertical direction. The actuator assembly 192 can be disposed in an atmospheric volume 168.

### CITATION LIST

### Patent Literature

PTL 1: JP2020-109847A

### SUMMARY OF INVENTION

### Technical Problem

However, since PTL 1 does not sufficiently consider the following points, it is thought that problems may occur.

That is, the actuator assembly 192 disclosed in PTL 1 is installed above a vacuum pump 182 in a flow module 106. Therefore, when the vacuum pump 182 and the substrate support assembly 118 including the actuator assembly 192 are arranged coaxially, the volume of a vacuum vessel including a chamber body 140 including the substrate support assembly 118 and the flow module 106 is expanded, a flow path through which gas and particles are exhausted by the vacuum pump 182 expands in the vertical direction, conductance of an exhaust flow deteriorates, and processing uniformity of a substrate 116 deteriorates, which is a point not considered in PTL 1.

Additionally, when radio frequency power is supplied to the substrate support assembly 118, in order to connect a chucking electrode 186 to a bias power supply 187, it is contemplated that a cable of a radio frequency power supply system is connected to a power source of the radio frequency power supply system through the back surface of the substrate support assembly 118, the inside of the hollow shaft 178, the atmospheric volume 168, and a through hole 170. In this case, when the substrate support assembly 118 is moved upwards and downwards, the cable of the radio frequency power supply system slides and, as such, impedance of the cable of the radio frequency power supply system changes, impedance of the radio frequency power supplied to the substrate support assembly 118 changes, and uniformity of the plasma processing of the substrate 116 deteriorates, which is another point not considered in PTL 1.

An object of the present disclosure is to provide a plasma processing apparatus capable of improving exhaust conductance in a vacuum vessel and generating stable plasma.

### Solution to Problem

A plasma processing apparatus of f the present disclosure has a plurality of drive actuators disposed outside a vacuum vessel, and the drive actuator and an outer peripheral portion of the bottom surface of a sample stage are connected to each other by a plurality of arms. The sample stage is driven upwards and downwards by driving the arms upwards and downwards using the drive actuators. Cables and the arms connected to the sample stage for power supply are vertically arranged in parallel, sliding of the cables is suppressed by performing a wiring route of the cables along the arms, and the volume of the vacuum vessel occupied by a sample stage unit is reduced.

### Advantageous Effects of Invention

According to the plasma processing apparatus, since a drive actuator is disposed outside a vacuum vessel, the vacuum vessel can be made small and conductance of the vacuum vessel can be improved. In addition, since wiring of a radio frequency power supply cable is performed along an arm of an outer peripheral portion that is disposed for the purpose of vertically driving a sample stage, a spatial distance between the sample stage and the radio frequency power supply cable is constant, and plasma is stably generated, thereby making it possible to improve plasma processing yield.

### BRIEF DESCRIPTION OF DRAWINGS

FIG. 1 is a vertical cross-sectional view schematically illustrating a configuration of a plasma processing apparatus according to an embodiment of the present disclosure.

FIG. 2 is an enlarged vertical cross-sectional view schematically illustrating a configuration around the periphery of a sample stage illustrated in FIG. 1.

FIG. 3 is a vertical cross-sectional view schematically illustrating a state in which the sample stage illustrated in FIG. 2 is raised.

FIG. 4 is a vertical cross-sectional view schematically illustrating a state in which the sample stage illustrated in FIG. 2 is lowered.

### DESCRIPTION OF EMBODIMENTS

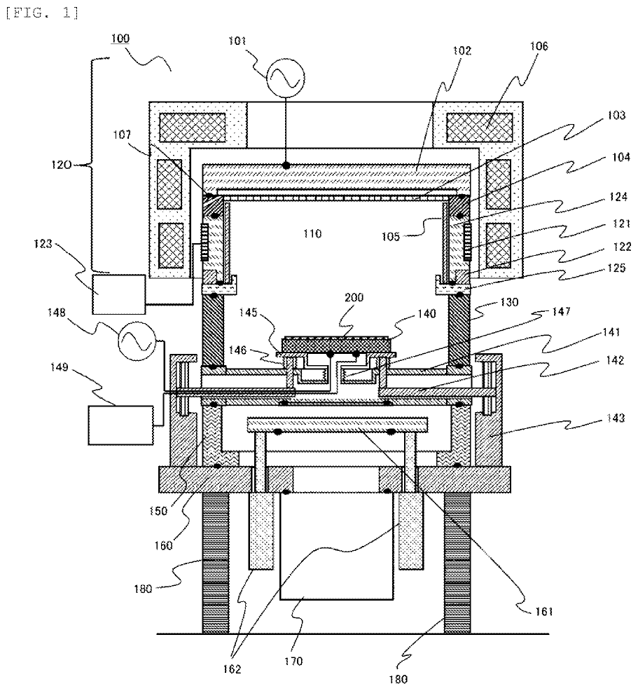

Hereinafter, embodiments and examples of the present disclosure will be described with reference to FIGS. 1 to 4.

### Embodiment

First, an overview of a plasma processing apparatus of the present disclosure will be described. A plasma processing apparatus (100) performs processing, by using plasma generated in a processing chamber (110), on a sample (200) having a substrate shape, such as a semiconductor wafer to be processed, in which the sample (200) is placed on a sample stage (140) disposed in the processing chamber (110) in a vacuum vessel and configured to support the wafer (200). Here, the sample (200), the sample stage, the vacuum vessel, and an exhaust pump (170) disposed at a lower portion of the vacuum vessel are coaxially arranged in a symmetrical manner, thereby having uniformity of a gas flow path shape. Further, since the plasma processing apparatus (100) includes a drive mechanism (143, 142, 214, 215) that drives the sample stage (140) upwards and downwards, it is possible to perform processing on the wafer (200) by freely and selectively adjusting the height of the sample stage (140) using the drive mechanism (143, 142, 214, 215).

More specifically, the plasma processing apparatus (100) includes the processing chamber (110) disposed in the vacuum vessel and configured to generate plasma therein, and the sample stage (140) disposed in the processing chamber (110) and configured to allow the semiconductor wafer (200) to be processed by plasma to be placed thereon.

Members forming the vacuum vessel have the following configuration.

(1) Upper vessel (130): an upper vessel (130) is placed on sample stage bases (141, 145) disposed so as to be connected to the sample stage (140) at the outer periphery of the sample stage (140) and is placed above the sample stage bases (141, 145), thereby having a cylindrical shape.

(2) Plurality of support beams (206): a plurality of support beams (206) connect the sample stage (140) to the sample stage bases (141, 145).

(3) Arm (142): an arm (142) is disposed in a space in the support beam (206), and one end thereof extends in the horizontal direction and is connected to a bottom portion of an outer peripheral portion of the sample stage (140), thereby vertically moving the space in the support beam (206).

(4) Drive unit (143, 214, 215): a drive unit (143, 214, 215) is disposed outside the vacuum vessel, is connected to the other end of the arm (142), and moves the arm (142) in the vertical direction.

(5) Cable (radio frequency power supply cable 210): a cable (210) is electrically connected to an electrode to which radio frequency power is supplied via a connector (211) disposed at a bottom portion of the sample stage (140), thereby allowing the radio frequency power to flow therethrough. The cable (210) is fixed to the arm (142) and moves in the vertical direction when the arm (142) is driven.

As a result, since the radio frequency power supply cable (210) is fixed along the arm (142) disposed for the purpose of vertically driving the sample stage (140), a spatial distance between the sample stage (140) and the radio frequency power supply cable (210) is constant and, as such, impedance of the radio frequency power supply cable does not change. Therefore, plasma can be stably generated, and the yield of plasma processing can be improved.

Furthermore, since the drive unit (143, 214, 215) is disposed outside the vacuum vessel, expansion of the volume of the vacuum vessel can be suppressed, and the vacuum vessel can be made relatively compact. As a result, a size of a flow path through which gas and particles are exhausted by the exhaust pump 170 is reduced in the vertical direction, thereby improving conductance of an exhaust flow. Therefore, processing uniformity of the substrate 200 is improved.

### EMBODIMENT

FIG. 1 is a vertical cross-sectional view schematically illustrating a configuration of a plasma processing apparatus according to an embodiment of the present invention. Particularly, FIG. 1 is a schematic diagram of a configuration of a main part of a plasma processing apparatus 100 including a vacuum vessel.

The plasma processing apparatus 100 illustrated in FIG. 1 includes a vacuum vessel including an upper vessel 130 and a lower vessel 150, a lower exhaust pump 170 connected to the vacuum vessel and disposed below the vacuum vessel, an upper first radio frequency power source 101, and a solenoid coil 106. The upper vessel 130 and the lower vessel 150 each have an inner wall having a circular horizontal cross section, and a cylindrical sample stage 140 is disposed at a central portion of the inner wall.

The sample stage 140 is held by a second sample stage base 145. The second sample stage base 145 has a disc shape, the central portion of which is recessed downwards in the vertical direction, and is coupled to at least two or more arms 142 at an outer peripheral portion thereof. The arm 142 is connected to a drive actuator 143 installed outside the vacuum vessels (130, 150). It is noted that the drive actuator 143 is connected to an upper portion of a base plate 160.

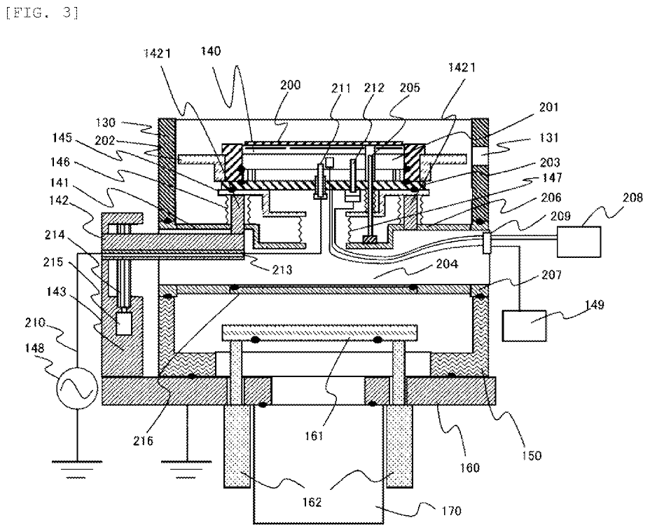

The outer walls of the upper vessel 130 and the lower vessel 150 form a vacuum partition. A first sample stage base 141 has a ring shape including a hollow support beam 206 (refer to FIG. 3). Here, this ring-shaped ring portion is held around the upper vessel 130 and the lower vessel 150 and is vacuum sealed. Further, the first sample stage base 141 is a path configured to connect, using a plurality of hollow support beams 206, the arm 142 that supports the sample stage 140 and the second sample stage base 145 to the drive actuator 143. It is noted that the hollow support beams 206 are arranged axially symmetrically with the vertical center of the sample stage 140 as an axis (in other words, a gas flow path shape is approximately coaxially symmetrical with respect to the central axis of the sample stage 140). A space defined from an opening communicating with the hollow support beam 206 of the first sample stage base 141 to a cylindrical cavity part below the second sample stage base 145 via a hollow part in the hollow support beam 206 in which the arm 142 is built has a path communicating with the surrounding space outside the plasma processing apparatus 100, and the space is under atmospheric pressure. Further, a space of the processing chamber 110 in the vacuum vessel is vacuum sealed by a plurality of outer peripheral bellows 146 and central bellows 147. Therefore, even when processing is performed on a wafer 200, it is possible to drive the sample stage 140 upwards and downwards by the drive actuator 143 in a state of maintaining the vacuum state in the vacuum vessel.

Gas and the like (processing gas, particles in plasma, and reaction products) in the space above the sample stage 140 in the upper vessel 130 pass through a space between the hollow support beams 206 that form the first sample stage base 141 and is exhausted through the lower vessel 150 and, as such, a gas flow becomes uniform in the circumferential direction of the sample stage 140 on which the wafer 200, which is an object to be processed (a sample), is placed, thereby making it possible to perform uniform processing on the wafer 200.

Further, the upper vessel 130, the lower vessel 150, and the base plate 160 each have a flange portion, and each of the upper vessel 130 and the lower vessel 150 is screwed to the base plate 160 at the flange portion. It is noted that, in this example, the processing chamber 110, which is a cylindrical space, is disposed in the vacuum vessel. Here, gas is introduced into the processing chamber 110, and an electric field and a magnetic field are supplied thereto, thereby forming plasma in the processing chamber 110. Although a member forming a vessel surrounding the processing chamber 110 has a cylindrical shape on the inside thereof, regarding the shape of the outer wall of the member, the horizontal cross-sectional shape of the member may have a rectangular shape instead of a circular shape or may have another shape.

On an upper portion of the processing chamber 110, a disk-shaped lid member 102 forming the vacuum vessel is disposed, and on a lower portion of the lid member 102, a disk-shaped shower plate 103 forming the ceiling surface of the processing chamber 110 is disposed. The lid member 102 and the shower plate 103 are members made of dielectric material such as quartz. For this reason, these members are configured to allow radio frequency electric fields such as microwaves, UHF, and VHF waves to pass therethrough. An electric field from the first radio frequency power source 101 disposed above the processing chamber 110 is supplied to the inside of the processing chamber 110 through the lid member 102 and the shower plate 103. In addition, on the outer periphery of an outer side wall of the vacuum vessel, the cylindrical coil (solenoid coil) 106 is disposed to surround the outer side wall as a means of forming a magnetic field, and the generated magnetic field is configured to be supplied to the inside of the processing chamber 110.

In the shower plate 103, a plurality of through introduction holes, which are a plurality of through holes, are disposed to allow processing gas to be introduced thereinto, and the processing gas introduced from a gas introduction ring 104 is supplied into the processing chamber 110 through the introduction holes. An O-ring 107 is provided between the lid member 102 and the gas introduction ring 104. The plurality of introduction holes of the shower plate 103 are arranged in an axially symmetrical area around the central axis of the sample stage 140 above the sample placement surface which is the upper surface of the sample stage 140. Here, processing gas made up of different gas components each having a predetermined composition is introduced into the processing chamber 110 through uniformly arranged introduction holes.

The processing gas introduced into the processing chamber 110 is excited by being supplied with an electromagnetic wave and a magnetic field generated by the first radio frequency power source 101 serving as an electric field formation means and the solenoid coil 106 serving as a magnetic field formation means, and the excited processing gas is turned into plasma in a space (a discharge section) above the sample stage 140, in which the space forms an upper portion of the processing chamber 110. The upper portion of the plasma processing apparatus 100 of the present embodiment forms a discharge block 120. The discharge block 120 includes: an upper portion of the vacuum vessel surrounding an area above the sample stage 140, in which the area allows the processing gas to be introduced thereinto so as to generate plasma; and the first radio frequency power source 101 and the solenoid coil 106 respectively disposed on the outside of the upper portion of the vacuum vessel and configured to cover the upper portion of the plasma processing apparatus 100.

Particularly, the discharge block 120, which is the upper portion of the vacuum vessel of the present embodiment, includes the lid member 102, the shower plate 103, or the gas introduction ring 104, and a discharge part chamber 124 having a cylindrical shape, in which the discharge part chamber 124 is disposed above a lower ring 122, the bottom surface of which faces and abuts an earth ring 125 to be described later, and is interposed between the gas introduction ring 104 and the lower ring 122. The space in which plasma is formed is surrounded by the discharge part chamber 124 and has at least a cylindrical shape. A heater 121 is attached to an outer peripheral side wall of the discharge part chamber 124 so as to surround the outer peripheral side wall of the discharge part chamber 124. Furthermore, the heater 121 receives power and a command signal from a first temperature controller 123 including a power source electrically connected to the heater 121, thereby adjusting an output of the heater 121 or an amount of heat generation. With such a configuration, it is possible to heat a quartz inner cylinder 105 disposed inside by opening a gap formed on the inner peripheral side wall surface of the discharge part chamber 124. The quartz inner cylinder 105 is configured to come into contact with plasma generated in the quartz inner cylinder 105.

With such a configuration, it is possible to reduce adhesion of a reaction product to the surfaces of members facing plasma in the discharge part including the quartz inner cylinder 105. Therefore, these members can be excluded from routine maintenance.

The central axis of the sample stage 140 on which the wafer 200 is placed is arranged in the processing chamber 110 so as to coincide with the central axis of the shower plate 103. The sample to be processed by plasma is the wafer 200, and the wafer 200 is placed on the circular placement surface which is the upper surface of the sample 140, and the wafer 200 is attracted and held stage 1 (electrostatic chuck) by an electrostatic charge of a dielectric film forming this placement surface. Processing is performed on the surface of the wafer 200 in a state in which the wafer 200 is held on the placement surface.

In the present embodiment, the wafer 200, which is a sample such as a semiconductor substrate, has a diameter of 300 mm. In consideration of the diameter thereof, the inner diameter of the cylindrical processing chamber 110, for example, the diameter of the inner wall surface of the upper vessel 130, is set to 600 mm. However, dimensions other than this diameter can also be used. For example, the diameter of the wafer 200 may be 450 mm, and the inner diameter of the processing chamber 110 may be 800 mm.

In addition, a radio frequency bias power source (a second radio frequency power source) 148 is connected to electrodes arranged in the sample stage 140. A radio frequency bias is formed, by the supplied radio frequency power, on the sample stage 140 and above the sample 200 placed on the sample stage 140. Etching processing is performed on the surface of the wafer 200 by mutual reaction between physical reaction caused by attracting charged particles in plasma to a surface of the sample using the radio frequency bias and causing the charged particles to collide with the surface of the sample, and chemical reaction between the radicals and the wafer surface. Further, the temperature of the sample stage 140 can be controlled to a desired temperature by a second temperature controller 149.

The application of the radio frequency bias to the sample stage 140 and the temperature control of the sample stage 140 are performed via a power wiring cord, a temperature control wiring cord, or a refrigerant pipe, in which the power wiring cord and the temperature control wiring cord are wired in a cavity formed in the first sample stage base 141 including the hollow support beam 206, in the central bellows 147, and in a cavity formed in the second sample stage base 145 (refer to FIG. 3). Although not illustrated, in addition to the wiring cords described above, wiring cords for a temperature sensor and an electrostatic chuck may also be included. Since a reaction product is likely to adhere to the upper vessel 130 disposed around the sample stage 140, the upper vessel 130 is a member subject to regular maintenance.

The base plate 160 having an exhaust opening and the exhaust pump 170 are disposed below the processing chamber 110. The exhaust pump 170 is connected to a bottom portion of the processing chamber 110 through the exhaust opening provided in the base plate 160. The exhaust opening provided in the base plate 160 is arranged directly below the sample stage 140. An exhaust part lid 161 having a substantially disk shape is disposed over the exhaust opening. A cylinder 162 adopted to move the exhaust part lid 161 upwards and downwards is connected to the exhaust part lid 161. By moving the exhaust part lid 161 upwards and downwards by the cylinder 162, exhaust conductance can be adjusted. The amount and speed of gas, plasma, and a product in the processing chamber 110 that are discharged to the outside of the processing chamber 110 are adjusted by the exhaust part lid 161 and the exhaust pump 170.

The exhaust part lid 161 is opened when processing is performed on the wafer 200, and pressure in the space inside the processing chamber 110 is maintained at a desired degree of vacuum by balancing the supply of the processing gas and the operation of an exhaust means such as the exhaust pump 170. In the present embodiment, the pressure during processing is adjusted to a predetermined value, for example, within a range of 0.1 to 4 Pa.

In the present embodiment, as the exhaust pump 170, for example, a roughing pump such as a rotary pump provided in a building where a turbo molecular pump and a vacuum processing apparatus are installed is used. It is noted that the exhaust part lid 161 is configured to be closed during maintenance so as to vacuum seal the exhaust pump 170 using an O-ring.

In the present embodiment, although not illustrated, a gate, which is an opening that performs communication between the inside of the vacuum vessel and the outside thereof, is disposed on an outer wall of the upper vessel 130, and the wafer 200 is placed on the sample stage 140 through the gate by a conveyance robot. Further, during plasma processing, the opening is vacuum sealed by a gate valve (not illustrated), and the vacuum sealing is released only when the wafer 200 is conveyed. Reference numeral 180 indicates a column supporting the plasma processing apparatus 100.

The pressure inside the processing chamber 110 during etching processing is monitored by a vacuum gauge (not illustrated), and the pressure inside the processing chamber 110 is controlled by controlling the exhaust speed using the exhaust part lid 161. The supply of these processing gases and the operation of an electric field formation means (101), a magnetic field formation means (106), a radio frequency bias (148), and exhaust means (161, 170) are controlled by a communicably connected control device (not illustrated).

As the processing gas used for the plasma processing, a single type of gas for each process condition or gas obtained by mixing a plurality of types of gas at an optimal flow rate ratio is used. The flow rate of this mixed gas is adjusted by a gas flow controller (not illustrated), and the mixed gas is introduced into a space for gas retention between the shower plate 103 and the lid member 102 disposed above the processing chamber 110 at the upper part of the vacuum vessel via the gas introduction ring 104 connected to the gas flow controller by a gas pipe. In the present embodiment, the gas introduction ring 104 made of stainless steel is used.

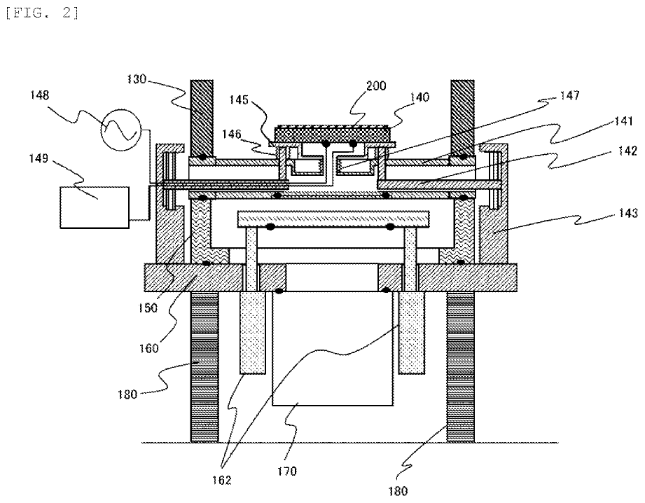

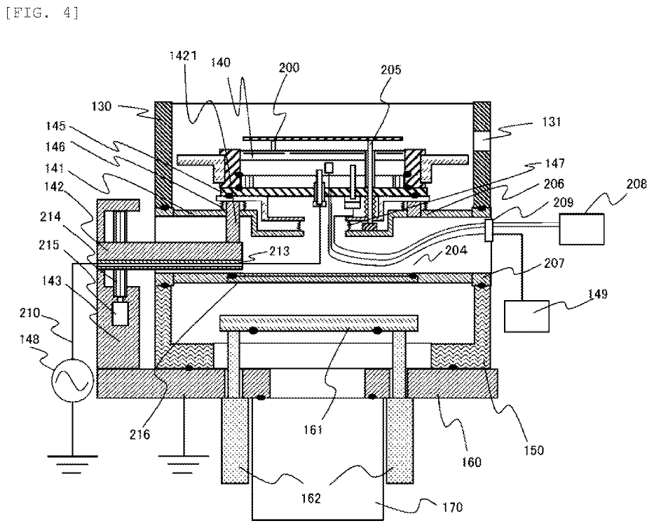

Next, a configuration of the plasma processing apparatus according to the present embodiment will be described in more detail with reference to FIGS. 2 to 4. FIGS. 2, 3, and 4 are longitudinal cross-sectional views schematically illustrating the configuration of the plasma processing apparatus according to the embodiment illustrated in FIG. 1. FIG. 2 is an enlarged vertical cross-sectional view schematically illustrating a configuration around the sample stage illustrated in FIG. 1. FIG. 3 is a vertical cross-sectional view schematically illustrating a state in which the sample stage illustrated in FIG. 2 is raised. FIG. 4 is a vertical cross-sectional view schematically illustrating a state in which the sample stage illustrated in FIG. 2 is lowered.

Particularly, FIG. 2 is a vertical cross-sectional view illustrating an enlarged lower portion of the plasma processing apparatus 100 illustrated in FIG. 1. FIG. 2 omits illustration of members such as the first radio frequency power source 101, the lid member 102, and the coil 106 which are disposed at the upper portion of the plasma processing apparatus 100. That is, a portion below the upper vessel 130 of the plasma processing apparatus 100 illustrated in FIG. 1 is illustrated in an enlarged manner. The plasma processing apparatus 100 illustrated in FIG. 2 broadly includes vacuum vessels (130, 150), a pedestal (160) disposed below the vacuum vessels (130, 150) so as to support the vacuum vessels (130, 150) from below, and an exhaust means (170) connected to a lower portion of the pedestal (160) and configured to communicate with the inside of the vacuum vessels (130, 150) so as to exhaust the inside thereof. It is noted that the first sample stage base 141 may be included in the vacuum vessels (130, 150).

It is noted that in this drawing, descriptions of the parts denoted by the reference numerals previously described in FIG. 1 will be omitted unless necessary. Furthermore, although not illustrated in the drawing, a gate, which is an opening that performs communication between the inside of the vacuum vessel and the outside thereof, is disposed on the outer wall of the upper vessel 130, and the wafer 200 is placed on the sample stage 140 through the gate by a conveyance robot. Further, during plasma processing, the opening is vacuum sealed by a gate valve (not illustrated), and the vacuum sealing is released only when the wafer 200 is conveyed.

The vacuum vessel of the plasma processing apparatus 100 in FIG. 2 includes the upper vessel 130, the first sample stage base 141 disposed below the upper vessel 130, and the lower vessel 150 disposed below the first sample stage base 141, and the vessels and the sample stage are arranged so as to form a layer in the vertical direction. The lower vessel 150 is placed so that the lower surface thereof is in contact with the upper surface of the base plate 160 serving as a pedestal. That is, the lower surface of the lower vessel 150 is placed on the upper surface of the base plate 160 and is fixed thereto such that the lower surface of the lower vessel 150 and the upper surface of the base plate 160 are in contact with each other. The lower vessel 150 is placed on the base plate 160 to form a vacuum vessel in a state in which the first sample stage base 141 and the upper vessel 130 are airtightly sealed inside and outside.

Further, the plasma processing apparatus 100 includes a plurality of columns 180 disposed below the lower surface of the base plate 160, in which each of the columns 180 serves as a pedestal and is configured to support the base plate 160 and the vacuum vessels (130, 150) disposed above the base plate 160. The upper ends of the plurality of columns 180 are connected to the lower surface of the base plate 160, and the lower ends of the plurality of columns 180 are connected to the upper surface of the floor of a building in which the plasma processing apparatus 100 is disposed.

The plasma processing apparatus 100 also includes the exhaust pump 170, the exhaust part lid 161, and the cylinder 162. In a space defined between the lower surface of the base plate 160 and the floor of the building and formed by allowing the base plate 160 to be supported by the columns 180, the exhaust pump 170 is disposed below a through hole in a state of communicating with the through hole located at a central portion of the base plate 160, and the same is configured to function as an exhaust port for internal exhaust gas. The exhaust part lid 161 is disposed in the lower vessel 150 and opens or airtightly closes the exhaust port. The cylinder 162 is an actuator that drives the exhaust part lid 161 upwards and downwards with respect to the exhaust port.

It is noted that in the plasma processing apparatus 100 as well, the base plate 160 is electrically connected to a ground electrode and set to a ground potential. Therefore, the lower vessel 150, the lower surface of which is in contact with and is connected to the base plate 160, the first sample stage base 141, and the upper vessel 130 are set to the ground potential.

The exhaust means (170) includes: the exhaust pump 170 such as a turbo molecular pump disposed below and configured to communicate with the exhaust port, which is a through hole, disposed in the lower vessel 150, and the base plate 160; and an exhaust duct (not illustrate) that connects an inlet of the exhaust pump 170 to an exhaust port thereof so as to enable the inlet and the exhaust port to communicate with each other. In the plasma processing apparatus 100 illustrated in FIG. 2 as well, the exhaust port of the exhaust pump 170 is connected to a rough grinding pump such as a rotary pump disposed in advance in the building in which the plasma processing apparatus 100 is installed. Further, the flow rate for speed of the exhaust gas discharged from the exhaust port can be adjusted by driving the exhaust part lid 161 using the cylinder 162, moving the exhaust part lid 161 upwards and downwards with respect to the exhaust port, and increasing or decreasing an area of an exhaust flow path to the exhaust port.

FIG. 3 is an enlarged vertical sectional view schematically illustrating a configuration of the main parts of the sample stage 140 having the wafer 200 placed thereon and including the first sample stage base 141 illustrated in FIG. 2. FIG. 3 is an enlarged view illustrating the configuration of the sample stage 140 in more detail. The sample stage 140 is disposed in the processing chamber 110 inside the vacuum vessel formed of the upper vessel 130, the first sample stage base 141, and the lower vessel 150, and holds the wafer 200 placed on the upper surface thereof.

FIG. 3 illustrates the state of the apparatus in which the sample stage 140, the second sample stage base 145, and the arm 142 are raised by the drive actuator 143 in the present embodiment, and the wafer 200 is undergoing plasma processing. Similar to FIG. 2, the plasma processing apparatus 100 illustrated in FIG. 3 arranges, in the vertical direction, the vacuum vessels (130, 150), the base plate 160 located below the vacuum vessel (130, 150), and the exhaust means (170) located below the base plate 160. Further, in the vacuum vessel, the upper vessel 130, the first sample stage base 141, and the lower vessel 150 are connected to each other in the vertical direction and are disposed so that the vertical central axes thereof coincide with each other in the vertical direction or are respectively disposed at approximate positions considered to be close thereto. Here, the internal side wall surfaces of the upper vessel 130, the first sample stage base 141, and the lower vessel 150 each have a cylindrical shape.

In other words, the arm 142 is disposed in the space in the hollow support beam 206. The arm 142 extends in the horizontal direction, and one end of the arm 142 extending in the horizontal direction is connected to the bottom portion of the outer periphery of the sample stage 140 so as to vertically move the space in the hollow support beam 206. The other end of the arm 142 is connected to an arm drive unit (the arm drive unit includes the drive actuator 143, a ball screw 214, and a motor 215) that moves the arm 142 in the vertical direction.

The gate 131, which is an opening that performs communication between the inside of the vacuum vessel and the outside of the vacuum vessel, is disposed on the outer wall of the upper vessel 130, and the wafer 200 is placed on the sample stage 140 through the gate 131 by a conveyance robot. Further, during plasma processing, the opening (the gate 131) is vacuum sealed by a gate valve (not illustrated), and the vacuum sealing is released only when the wafer 200 is conveyed.

A sample stage block includes: the first sample stage base 141, which roughly forms a lower portion of the sample stage block; the sample stage 140 mounted on the sample stage base 141 so as to be connected thereto and configured to include a cylindrical head part 201; and an outer peripheral ring 202 disposed above the first sample stage base 141 and disposed on an outer peripheral side of the sample stage 140 so as to surround the first sample stage base 141 and the outer peripheral side thereof, in which the outer peripheral ring 202 is disposed in a ring shape. In the present embodiment, during work in which the plasma processing apparatus 100 undergoes maintenance such as parts replacement and inspection, the parts are configured to be detachable and replaceable from the vacuum vessel or the lower portion of the vacuum vessel in a state in which the inside of the vacuum vessel is brought to atmospheric pressure and the vacuum vessel is opened.

The head part 201 forming the upper portion of the sample stage 140 includes the base plate 203, which is a circular metal plate-like member, a metal base material having a disk or cylindrical shape placed above the base plate 203, and a dielectric film disposed to cover the circular upper surface of the base material. The base plate 203 and the base material having the dielectric film are connected to each other and are configured to be detachable as a unit, as described later.

The second sample stage base 145 is a circular member that functions as a pedestal for mounting the sample stage 140 on the upper portion of the second sample stage base 145. Here, the head part 201 including the sample stage 140 is placed above a central portion of the second sample stage base 145, and the upper surface of the outer periphery of the second sample stage base 145 is connected to the lower surface of the outer periphery of the base plate 203.

In addition, as compared with the outer peripheral portion of the second sample stage base 145, the central portion of the second sample stage base 145 has a circular shape with a downwardly convex cross section, and a space surrounded by the upper surface of the central portion of the second sample stage base 145, the side surfaces, and the lower surface of the base plate 203 is a storage space 204. As described later, the storage space 204 is a space in which at least an extension path of a plurality of fixing pins 205 for lowering the head part 201 and separating the wafer 200 from the sample stage 140 during conveyance of the wafer 200, a power supply connector 211 to the head part 201 that comes out from the base plate 203, a sensor, and the like can be arranged. Here, the storage space 204 is kept at atmospheric pressure or the same pressure as the pressure inside the building in which the plasma processing apparatus 100 is installed, and the bottom surface of the central portion of the second sample stage base 145 has an opening large enough to perform wiring of at least a cable connected to the head part 201.

The bottom surface of the outer peripheral portion of the second sample stage base 145 is an area to which the arm 142 that drives the sample stage 140 upwards and downwards and the outer peripheral bellows 146 are coupled. As mentioned above, the central portion of the second sample stage base 145 has the storage space 204 formed at the upper portion of the second sample stage base 145 and surrounded by the lower surface of the base plate 203. As compared with the bottom surface of the central portion of the second sample stage base 145, the bottom surface of the outer peripheral portion of the second sample stage base 145 is at least higher than the minimum surface distance of the outer peripheral bellows 146, and there is enough space to dispose the bellows 146 therein.

The first sample stage base 141 includes: a ring-shaped base ring 207 that forms the outermost peripheral portion and has upper and lower portions thereof interposed between the upper vessel 130 and the lower vessel 150 so as to form the vacuum vessel; a central cylinder having a cylindrical shape disposed on the center side of the base ring 207; and a plurality of support beams 206 integrally formed by connecting a space therebetween. In the present embodiment, the inner periphery of the base ring 207 and the outer periphery of the central cylinder have cylindrical shapes respectively having different radii, in which central portions of the cylindrical shapes thereof coincide with each other in the vertical direction or are respectively disposed at approximate positions in the horizontal direction where the central portions are almost considered to coincide with each other. The support beams 206 have axes thereof radially disposed in the radial direction from the position of the central axis. Here, the support beams 206 are disposed in such a manner that angles between the axes of the adjacent support beams 206 are equal to each other, or the angles therebetween are slightly different from each other but are almost considered to be the same. Further, the first sample stage base 141 has a cylindrical concave portion in which the central height of the central cylinder is lower than the top surface of the base ring 207, and this concave portion has a height sufficient enough to dispose at least the central bellows 147 and the fixing pin 205 therein. In the present embodiment, the concave portion formed at the central portion of the first sample stage base 141 is a space having a larger diameter than that of a convex portion formed at the central portion of the second sample stage base 145. However, as long as the central bellows 147 and the fixing pin 205 can be disposed in the concave portion, the concave portion formed at the central portion of the first sample stage base 141 may be smaller.

The first sample stage base 141 is a member connected to the aforementioned second sample stage base 145 by a plurality of outer peripheral bellows 146 and the central bellows 147, and the processing chamber 110 and the storage space 204 are airtightly sealed by the central bellows 147. Therefore, the storage space 204 is a space in which the lower surface of the base plate 203, the upper surface of the central portion of the second sample stage base 145, the side surfaces of the central portion of the second sample stage base 145, the inside of the central bellows 147, the inside of the hollow support beam 206, and the upper surface of a sample stage lid 216 communicate with each other. Here, each connection point is vacuum sealed by an O-ring and is brought to atmospheric pressure or the same pressure as the pressure inside the building in which the plasma processing apparatus 100 is installed. The communicable storage space 204 serves as a wiring route for a power supply cable to the head part 201 connected to the base plate 203.

At least two drive actuators 143 serving as arm drive units are disposed on the outer periphery of the base plate 160 at a symmetrical angle with respect to the central axis of the first sample stage base 141. Here, the drive actuator 143 is formed of the ball screw 214, the motor 215, and members respectively that support the ball screw 214 and 214 are the motor 215. The arm 142 and the ball screw 2 connected to each other at the outside of the plasma processing apparatus 100. The ball screw 214 is connected to the motor 215, and the drive actuator 143 includes a guide (not illustrated) that assists the linear movement of the arm 142.

Although not illustrated, the drive actuators 143 are connected to each other by communication cables and are controlled so as to synchronize the rotation angle and rotation speed of the motor 215, that is, the height of the arm 142.

In the storage space 204 described above, in addition to the extension path for the plurality of fixing pins 205, various types of wiring such as a pipe for a refrigerant supplied to the head part 201 and a power supply cable to a sensor or an electrode are disposed. The central bellows 147 in which wiring is arranged has a cylindrical space at the inside thereof, and the space at the inside thereof is limited to usage as a wiring route for a power supply cable to the head part 201 and the like. Further, the outer peripheral bellows 146 has a cylindrical space at the inside thereof, and the space at the inside thereof is limited to usage as a connection path for the arm 142 that is coupled to the second sample stage base 145. The inside of the hollow support beam 206 is a part of the storage space 204 and serves as a space having a pipe or a cable disposed therein and adopted to connect the sample stage 140 to a power supply or a refrigerant supply source disposed outside the plasma processing apparatus 100, or a space having the arm 142 installed therein and coupled to the second sample stage base 145.

In other words, the storage space 204 can be regarded as a path communicating with a space maintained at atmospheric pressure outside the plasma processing apparatus 100 and a cylindrical cavity part surrounding a space below the bottom surface of the sample stage 140, in which an end of a coaxial cable 210 to be described later connected to the power supply connector 211 to be described later is disposed in the space. Here, the arm 142 is disposed in this path.

A columnar member 1421 is disposed at one end of the arm 142. The columnar member 1421 is configured to connect the arm 142 to the bottom portion of the outer peripheral portion of the sample stage 140 so as to support the sample stage 140. A plurality of outer peripheral bellowses 146 are provided around the plurality of columnar members 1421. The plurality of outer peripheral bellowses 146 are disposed around the periphery of the columnar member 1421 disposed between the upper surface of the cylindrical cavity part and the bottom portion of the outer peripheral part of the sample stage 140. Here, the outer peripheral bellowses 146 expand and contract when the arm 142 moves upwards and downwards, thereby airtightly sealing a space defined between the inside of the cavity part and the inside of the processing chamber 110.

A plurality of temperature sensors 212 are inserted into a plurality of concave portions disposed in a base material of the sample stage 140 so as to detect the temperature of the base material. One ends of the plurality of temperature sensors 212 are arranged in the storage space 204. The other ends of the plurality of temperature sensors 212 are connected to a vessel controller 208 disposed outside the base ring 207 or the plasma processing apparatus 100 by a cable passing through a space in the hollow support beam 206. The plurality of temperature sensors 212 and the vessel controller 208 can communicate with each other by the cable. The vessel controller 208 is configured to receive an output of each of the temperature sensors 212 transmitted during processing of the wafer 200.

The head part 201 forming the sample stage 140 of the present embodiment includes the base plate 203, an insulating member (not illustrated) placed above the base plate 203, and a metal base material (not illustrated) placed above the insulating member. A dielectric film (not illustrating) is disposed on the upper surface having a disk or cylindrical shape of the head part 201, in which the dielectric film contains ceramics such as yttria or alumina that forms the placement surface having the wafer 200 placed thereon. Further, a sealing member such as an O-ring is interposed between the respective structural members and is integrally connected thereto, and the inside of the plasma processing apparatus 100 and the space inside the sample stage blocks (141, 140, 202) communicating with the storage space 204 are airtightly sealed. Additionally, the head part 201 is mounted on the second sample stage base 145 as a collective member and is configured to be removable upwards.

In addition, the metal base material (not illustrated), which is a component of the head part 201, is supplied with radio frequency power, the frequency of which is lower than a frequency of an electric field for forming plasma during processing of the wafer 200, and a bias potential is formed on the wafer 200 placed on the upper surface of the dielectric film. In the present embodiment, the power supply connector 211 adopted to receive the radio frequency power for forming the bias potential from the second radio frequency power source 148 is inserted into the base material and, as such, in the electrically connected state, the power supply connector 211 is attached to the head part 201 and is wired with the coaxial cable 210. The coaxial cable 210 exits the power supply connector 211 and exits the plasma processing apparatus 100 through a coaxial cable path 213 provided along the central bellows 147 and the arm 142 in the storage space 204. Thereafter, the cable 210 is connected to the second radio frequency power source 148. In the present embodiment, the coaxial cable path 213 extends along the arm 142 from the storage space 204 to the outside of the plasma processing apparatus 100. Further, the coaxial cable path 213 is a path having an opening large enough for at least the coaxial cable 210 to pass through the opening, and is fixed in position by a fixture (not illustrated) installed at the end of the arm 142. In other words, the arm 142 includes the arm inner path 213 formed therein and configured to perform communication between the space 204 formed in the cavity part and the space maintained at atmospheric pressure outside the plasma processing apparatus 100 outside the sample stage base 145, and the coaxial cable 210 is disposed in the arm inner path 213 so as to fix the position of the path 213. However, if the path 213 can be fixed in position, the path 213 may be provided, for example, on the side surface of the arm 142, and may be fixed in position at a plurality of locations along the arm 142 with a bracket or the like. Furthermore, since the arm 142 is connected to the head part 201 including the power supply connector 211 and the second sample stage base 145, these positional relationships remain unchanged regardless of the vertical driving of the drive actuator 143. Therefore, even when the head part 201 moves upwards and downwards, the coaxial cable 210 does not come into contact with other cables or the inner wall or is not deformed in the storage space 204, thereby making it possible to suppress a change in impedance of radio frequency power due to deformation of the cable 210 and to generate stable plasma.

Additionally, the inside of the hollow support beam 206 in which the arm 142 is not disposed is a wiring route for a refrigerant pipe except for the coaxial cable 210, a cable for the temperature sensor 212, a power supply cable, and the like. Here, in order to prevent the cables from sliding outside the plasma processing apparatus 100, the cables are gathered and fixed by a cable fixture 209 connected to the outer peripheral portion of the hollow support beam 206. The fixture is a metal or resin fixture having an opening, the area of which is at least larger than the cross-sectional area of the cables to be gathered and fixed, and is connected to the base ring 207. The head part 201 moves the cables fixed by the fixture upwards and downwards. Here, since the cables are disposed with sufficient extra length and arrangement so that, even if the cables slide in the storage space 204, the cables do not touch the inner wall and the central bellows 147.

Furthermore, although not illustrated, a refrigerant flow path is provided in the metal base material which is a component of the head part 201. Here, a refrigerant, the temperature of which is adjusted to a value within a predetermined range, is supplied to the refrigerant flow path and is circulated therein. The temperature of such a refrigerant is adjusted in the second temperature controller 149 equipped with a temperature controller using a refrigeration cycle such as a chiller, and the refrigerant is supplied to the refrigerant flow path in the base material of the head part 201 by a pump in the second temperature controller 149. The refrigerant discharged after exchanging heat with the base material of the head part 201 is returned to the second temperature controller 149 via the refrigerant flow path, and the temperature thereof is adjusted again. Thereafter, the refrigerant is supplied to the refrigerant flow path in the base material. As described above, the refrigerant pipe connecting the refrigerant flow path to the second temperature controller 149 is disposed in the storage space 204 including the space of the hollow support beam 206.

Three fixing pins 205 are installed at equal intervals in the concave portion formed at the central portion of the first sample stage base 141. Further, the fixing pin 205 extends to the storage space 204 in the second sample stage base 145 and the head part 201. Since an extension part of the fixing pin 205 is in the vacuum atmosphere, the extension part is vacuum sealed by a bellows in the part of the storage space 204, and a through hole is provided in the head part 201 so as to avoid the aforementioned metal base material or the refrigerant flow path. That is, the through hole through which the fixing pin 205 is installed is installed in the head part 201.

The lower surface of the central cylinder forming the first sample stage base 141 is configured to allow the sample stage lid 216 to be attached thereto and detached therefrom, and the sample stage lid 216 is attached to the central cylinder so as to airtightly seal and close the internal storage space 204. The storage space 204 includes a cylindrical space disposed in each of the support beams 206 and the base ring 207 and configured to communicate with the inside of the central cylinder and the outside of the plasma processing apparatus 100 in a state of penetrating the same. As described above, when maintenance work such as parts replacement and inspection of the head part 201 is performed, the sample stage lid 216 is removed first, and the coaxial cable, the power wiring cord, the temperature control wiring cord, and the refrigerant pipe connected to the bottom surface of the base plate 203 are cut off in the storage space 204 below the central bellows 147. Thereafter, a fastening bolt fixing the base plate 203 and the second sample stage base 145 is removed, thereby making it possible to pull up the head part 201 in the vertical direction.

The vessel controller r 208 includes a calculation device and is placed outside the plasma processing apparatus 100 or the vacuum vessel, and is communicatively connected to a plurality of devices such as the sample stage 140 and the drive actuator 143. The vessel controller 208 receives a signal from a communicably connected device and detects information included in the signal, transmits a command signal to the device, and adjusts the operation thereof.

In addition, in this example, a connection between the vessel controller 208 and the drive actuator 143 is configured not to be disconnected, but the present invention is not limited thereto. The connection between the vessel controller 208 and the drive actuator 143 may be configured to be disconnected.

The vessel controller 208 of the present embodiment includes a computing unit formed of semiconductor devices, an interface that transmits and receives a signal to and from a device, and a storage device including a memory device such as an RAM or an ROM or a hard disk drive that records or stores data internally. These circuits (the computing unit, the interface, and the storage device) are communicably connected to each other in the vessel controller 208. The vessel controller 208 receives a signal from the outside through the interface, and the computing unit detects information from the signal and stores the information in the storage device. In addition, the computing unit reads out software stored in advance in the storage device, calculates a command signal corresponding to internal information of the previous signal (information stored in the storage device) according to an algorithm written in the software, and transmits the command signal to a device to be controlled through the interface.

The storage device of the vessel controller 208 may be housed in the vessel controller 208 or may be placed outside the vessel control 208 so as to perform communication. The vessel controller 208 of the present embodiment is communicably connected to the temperature sensor 212.

FIG. 4 illustrates the same configuration as that of the embodiment in FIG. 3, and is a vertical cross-sectional view schematically illustrating a state in which the drive unit including the sample stage 140, the second sample stage base 145, and the arm 142 is lowered to the lowest position thereof by the drive actuator 143. FIG. 4 illustrates each of a state in which the wafer 200 before or after plasma processing is conveyed from the plasma processing apparatus 100 and a state in which the wafer 200 before or after plasma processing is taken out therefrom. It is noted that, in FIG. 4, descriptions of the parts denoted by the reference numerals previously described in FIG. 3 will be omitted unless necessary.

The plurality of outer peripheral bellows 146 and center bellows 147 connected between the first sample stage base 141 and the second sample stage base 145 and configured to vacuum seal the processing chamber 110 and the storage space 204 are lowered by a driving amount of the drive actuator 143, as compared with the schematic diagram in FIG. 3 showing the state in which the outer peripheral bellows 146 and the central bellows 147 are raised.

As described above, the coaxial cable 210 is connected to the second radio frequency power source 148 disposed outside the plasma processing apparatus 100 through the dedicated coaxial cable path 213 provided inside the arm 142 or on the side surface thereof. As can be seen by comparing FIGS. 3 and 4, the position of the cable 210 is fixed in the storage space 204 by allowing the capable 210 to pass through the coaxial cable path 213, thereby making it possible to suppress a change in the impedance of radio frequency power due to deformation of the cable 210.

The inside of the hollow support beam 206 in which the arm 142 is not disposed is a wiring route for a refrigerant pipe except for the coaxial cable 210, a cable for the temperature sensor 212, a power supply cable, and the like. Here, in order to prevent the cables from sliding outside the plasma processing apparatus 100, the cables are gathered and fixed by the cable fixture 209 connected to the outer peripheral portion of the hollow support beam 206. The fixture is a metal or resin fixture having an opening, the area of which is at least larger than the cross-sectional area of the cables to be gathered and fixed, and is connected to the base ring 207. The head part 201 moves the cables fixed by the fixture 209 upwards and downwards. Here, since the cables are disposed with sufficient extra length and arrangement so that, even if the cables slide in the storage space 204, the cables do not touch the inner wall and the central bellows 147.

Only when the wafer 200 is placed on the sample stage 140 via the gate 131 for plasma processing, or only when the wafer 200 that has undergone plasma processing is conveyed out of the plasma processing apparatus 100 via the gate 131 by a conveyance robot (not illustrated), the three fixing pins 205 separate the wafer 200 from the sample stage 140 and hold the same. In the present embodiment, when the wafer 200 is conveyed into the plasma processing apparatus 100 and is conveyed out of the plasma processing apparatus 100, the drive actuator 143 causes the placement surface of the sample stage 140 on which the wafer 200 is placed to be lower than the height of the upper tip of the fixing pin 205. As a result, the back surface of the wafer 200 is separated from the placement surface of the sample stage 140 on which the wafer 200 is placed by the fixing pin 205.

On the other hand, in plasma processing, the placement surface of the sample stage 140 on which the wafer 200 is placed is positioned to be higher than the upper tip of the fixing pin 205. Accordingly, the back surface of the wafer 200 is in a state of contacting the placement surface of the sample stage 140 on which the wafer 200 is placed. In this state, plasma processing is performed or plasma processing is in progress. Further, the length of the fixing pin 205 is determined depending on the position of the gate 131, and it is necessary that a vertical drive stroke by the drive actuator 143 is performed so that at least the sample stage 140 during plasma processing exceeds the height of the fixing pin 205.

Although the present disclosure has been specifically described based on the embodiments, it goes without saying that the present invention is not limited to the embodiments and examples described above, and can be modified in various ways.

### REFERENCE SIGNS LIST

100: plasma processing apparatus
101: first radio frequency power source
102: lid member (quartz plate)
103: shower plate
104: gas introduction ring
105: quartz inner cylinder
106: coil
107: O-ring
110: processing chamber
120: discharge block
121: heater
122: lower ring
123: first temperature controller
124: discharge part chamber
125: earth ring
130: upper vessel
131: gate
140: sample stage
141: first sample stage base
142: arm
143: drive actuator
144: sample stage bottom lid
145: second sample stage base
146: outer peripheral bellows
147: central bellows
148: second radio frequency power source
149: second temperature controller
150: lower vessel
160: base plate
161: exhaust part lid
162: cylinder
170: exhaust pump
180: column
200: wafer
201: head part
202: outer peripheral ring
203: base plate
204: storage space
205: fixing pin
206: hollow support beam
207: base ring
208: vessel controller
209: cable fixture
210: coaxial cable
211: power supply connector
212: temperature sensor
213: coaxial cable path
214: ball screw
215: motor
216: sample stage lid

1. A plasma processing apparatus comprising:
a processing chamber disposed in a vacuum vessel and configured to generate plasma therein;
a sample stage disposed in the processing chamber and configured to allow a semiconductor wafer to be processed by the plasma to be placed thereon;
a ring-shaped sample stage base and an upper vessel each serving as a member forming the vacuum vessel, wherein the sample stage base is disposed at an outer periphery of the sample stage and is connected to the sample stage, and the upper vessel has a cylindrical shape and is placed on an upper portion of the sample stage base;
a plurality of support beams connecting the sample stage to the sample stage base;
an arm disposed in an internal space of the support beam, wherein the arm has one end formed to extend in a horizontal direction and connected to a bottom portion of an outer peripheral portion of the sample stage so as to move the internal space of the support beam in a vertical direction;
a drive unit disposed outside the vacuum vessel and connected to the other end of the arm so as to move the arm in the vertical direction; and
a cable electrically connected to an electrode having radio frequency power supplied thereto through a connector disposed at the bottom portion of the sample stage and configured to allow the radio frequency power to flow therethrough, wherein the cable is fixed to the arm and is moved in the vertical direction when the arm is driven.

2. The plasma processing apparatus according to claim 1, wherein:
the support beam has a path configured to allow a cylindrical cavity part surrounding a space, formed below a bottom surface of the sample stage and configured to allow an end of the cable connected to the connector to be disposed therein, and a space, formed outside the sample stage base and maintained under atmospheric pressure outside the plasma processing apparatus, to communicate with each other; and
the arm is disposed in the path.

3. The plasma processing apparatus according to claim 2, further comprising:
a columnar member disposed at the one end of the arm and configured to connect the arm to the bottom portion of the outer peripheral portion of the sample stage so as to support the sample stage; and
an outer peripheral bellows disposed around the columnar member between an upper portion of the cylindrical cavity part and the bottom portion of the outer peripheral portion of the sample stage and configured to expand and contract by vertical movement of the arm, wherein the outer peripheral bellows airtightly seals a space between an inside of the cavity part and an inside of the processing chamber.

4. The plasma processing apparatus according to claim 2, further comprising an arm inner path provided in the arm and configured to perform communication between the space in the cavity part and the space formed outside the sample stage base and maintained under the atmospheric pressure outside the plasma processing apparatus,
wherein the cable is disposed in the arm inner path so as to fix a position of the arm inner path.

5. The plasma processing apparatus according to claim 1, wherein:
the vacuum vessel includes a base plate configured to allow the sample stage base and the upper vessel to be placed thereon in a state of being airtightly sealed inside and outside so as to form the vacuum vessel; and
the drive unit is disposed on the base plate.

6. The plasma processing apparatus according to claim 1, wherein the vacuum vessel includes:
a lower vessel having a cylindrical shape, wherein the lower vessel is disposed below the sample stage base and has the sample stage base placed thereon; and
a base plate configured to allow the lower vessel, the sample stage base, and the upper vessel to be placed thereon in a state of being airtightly sealed inside and outside so as to form the vacuum vessel, and
wherein the drive is disposed on the base plate.

7. The plasma processing apparatus according to claim 2, wherein:
the vacuum vessel includes a base plate configured to allow the sample stage base and the upper vessel to be placed thereon in a state of being airtightly sealed inside and outside so as to form the vacuum vessel; and
the drive unit is disposed on the base plate.

8. The plasma processing apparatus according to claim 2, wherein the vacuum vessel includes:
a lower vessel having a cylindrical shape, wherein the lower vessel is disposed below the sample stage base and has the sample stage base placed thereon; and
a base plate configured to allow the lower vessel, the sample stage base, and the upper vessel to be placed thereon in a state of being airtightly sealed inside and outside so as to form the vacuum vessel, and
wherein the drive is disposed on the base plate.
